(19) United States
(12) Patent Application Publication
(10) Pub. No.: US 2026/0354182 A1
(43) Pub. Date: Nov. 5, 2026

(54) THERMAL STRUCTURES FOR SEMICONDUCTOR PACKAGES

(71) Applicant: Taiwan Semiconductor Manufacturing Co., Ltd., Hsinchu (TW)

(72) Inventors: Chien-Chang Wang, Hsinchu (TW); Ching Wang, Taichung City (TW); Bang Li Wu, Hsinchu (TW); Kuo-Chin Chang, Chiayi City (TW); Kathy Wei Yan, Hsinchu (TW); Jun He, Zhubei City (TW)

(21) Appl. No.: 19/738,941

(22) Filed: Jul. 13, 2026

Related U.S. Application Data
(63) Continuation of application No. 18/971,836, filed on Dec. 6, 2024.
(60) Provisional application No. 63/680,151, filed on Aug. 7, 2024.

(51) Int. Cl. H10W 40/28; H10W 40/22; H10W 40/47; H10W 40/73; H10W 42/00; H10W 70/02; H10W 70/05; H10W 90/00; H10W 70/685; H10W 72/00; H10W 74/10

(52) U.S. Cl. CPC H10W 40/28; H10W 40/226; H10W 40/228; H10W 40/47; H10W 40/73; H10W 42/00; H10W 70/023; H10W 70/095; H10W 90/401; H10W 42/121; H10W 70/685; H10W 72/0198; H10W 74/141; H10W 90/00; H10W 90/794

(57) ABSTRACT

A method includes forming a package component, including forming a thermal via extending through a substrate; and bonding a die to the thermal via; attaching the thermal via of the package component to a first conductive pad of a package substrate, wherein the package substrate includes a heat pipe underneath the first conductive pad; and attaching a support structure to a second conductive pad of the package substrate, wherein the heat pipe is underneath the second conductive pad, wherein the support structure includes a first thermoelectric cooler.

### PRIORITY CLAIM AND CROSS-REFERENCE

This application is a continuation of U.S. Application No. 18/971,836, filed Dec. 6, 2024, and entitled “Thermal Structures for Semiconductor Packages,” which claims priority to U.S. Provisional Application No. 63/680,151, filed on Aug. 7, 2024, which applications are hereby incorporated herein by reference.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed. For example, one problem of concern is stress within a package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, and 5 illustrate cross-sectional views of intermediate steps in the formation of a package component, in accordance with some embodiments.

FIG. 6 illustrates a cross-sectional view of a package substrate, in accordance with some embodiments.

FIG. 7 illustrates a cross-sectional view of an intermediate step in the formation of a package, in accordance with some embodiments.

FIGS. 8A and 8B illustrate plan views of support structures, in accordance with some embodiments.

FIGS. 9 and 10 illustrate cross-sectional views of intermediate steps in the formation of a package, in accordance with some embodiments.

FIGS. 10, 11, and 12 illustrate cross-sectional views of intermediate steps in the formation of a structure including a package, in accordance with some embodiments.

FIGS. 13, 14, 15, and 16 illustrate schematic plan views of packages, in accordance with some embodiments.

FIG. 17 illustrates a cross-sectional view of an intermediate step in the formation of a package including a lid, in accordance with some embodiments.

FIGS. 18 and 19 illustrate cross-sectional views of intermediate steps in the formation of a package structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

In accordance with some embodiments of the present disclosure, thermal structures are incorporated into a package to improve thermal performance. The thermal structures may include thermal vias formed in a package component, thermal pads formed in a package substrate, and thin heat pipes formed in the package substrate. Thermoelectric coolers (TECs) may also be formed in a support structure to provide additional heat dissipation. Various arrangements and configurations of thermal structures and TECs are possible, which may be chosen to provide efficient heat dissipation. Some techniques described herein allow for improved heat dissipation, reduced manufacturing cost, and improved device performance. The techniques described herein may apply to a variety of packaging technologies, such as System on an Integrated Circuit (SoIC) technology or the like.

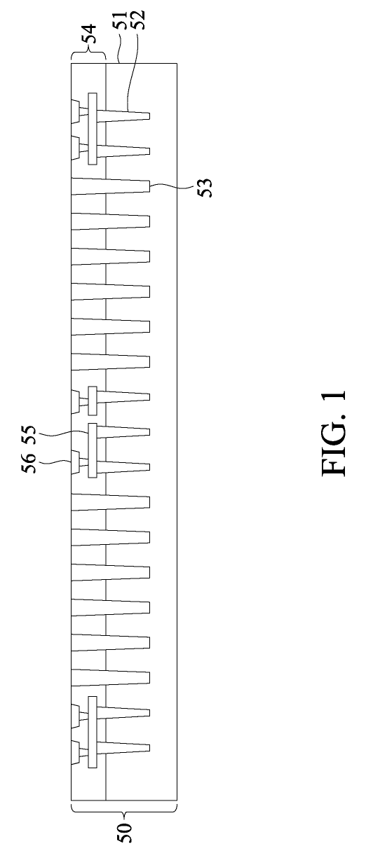

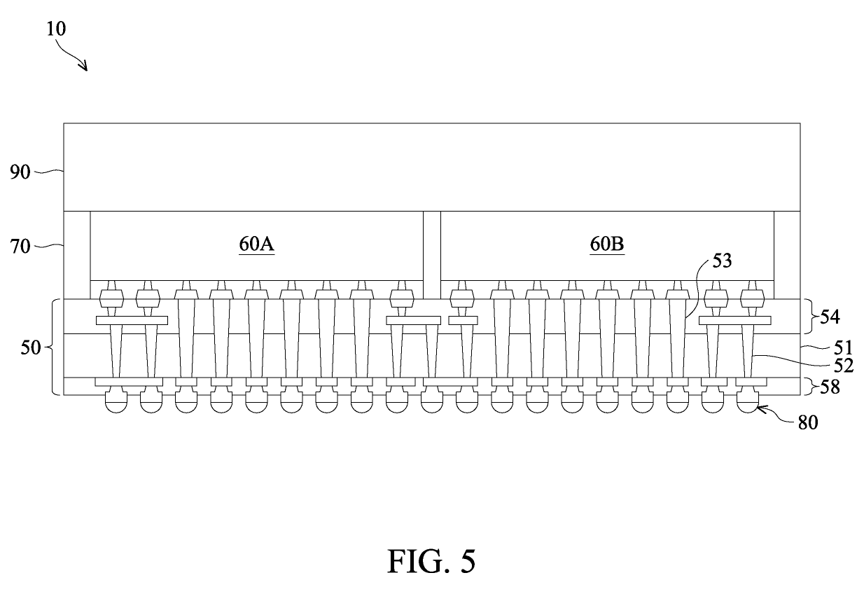

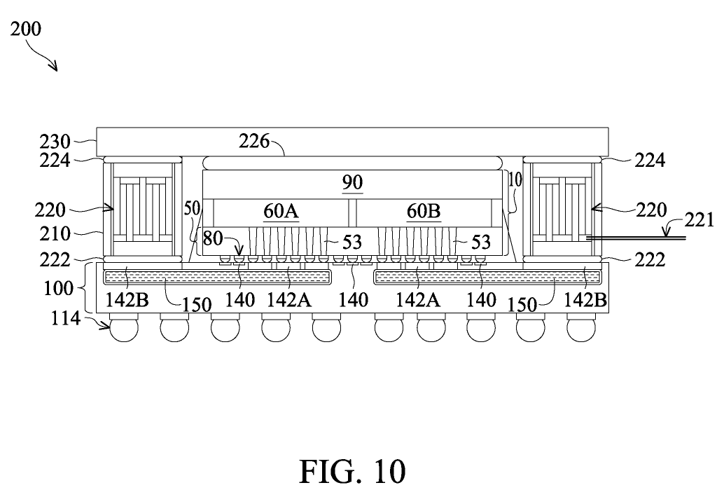

FIGS. 1-5 illustrate intermediate steps in the formation of a package component 10 (see FIG. 5), in accordance with some embodiments. In some embodiments, multiple package components 10 may be at least partially formed on a single wafer 50 and then subsequently singulated into individual package components 10. The package component 10 described for FIGS. 1-5 is an example, and other package components 10 or manufacturing steps thereof are possible. The package component 10 is subsequently incorporated into a package 200 (see FIG. 10).

In FIG. 1, a wafer 50 is formed or provided, in accordance with some embodiments. The wafer 50 may be processed according to applicable manufacturing processes to form devices, integrated circuits, interconnect structures or the like. In some embodiments, the wafer 50 may be an integrated circuit die, an interposer, an interconnect structure, or the like. In accordance with some embodiments, the wafer 50 may include a substrate 51, through-substrate vias (TSVs) 52, thermal vias 53, and an interconnect structure 54. The substrate 51 may be a semiconductor substrate, such as a bulk semiconductor, a semiconductor-on-insulator (SOI) substrate, or the like, which may be doped (e.g., with a p-type or an n-type dopant) or undoped. The substrate 51 may be a wafer, such as a silicon wafer. Other substrates, such as a silicon-on-insulator (SOI) substrate, a multi-layered substrate, or a gradient substrate may also be used. In some embodiments, the semiconductor material of the substrate 51 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. In some embodiments, multiple package components 10 may be formed on the same substrate 51 and then subsequently separated into individual package components 10 using a singulation process (e.g., a sawing process, dicing process, or the like).

Further, integrated circuit devices (not separately illustrated) may be formed at a front-side surface of the substrate 51, in some embodiments. The integrated circuit devices may include active devices (e.g., NMOS and PMOS transistors, diodes, etc.), passive devices (e.g., resistors, capacitors, etc.), and the like. In other embodiments, active devices and/or passive devices are not formed in the wafer 50. In some cases, the wafer 50 may be considered a “bottom die” or the like.

In some embodiments, an interconnect structure 54 is formed over the front-side of the substrate 51. The interconnect structure 54 includes conductive features 55 formed in one or more dielectric layers (not separately illustrated). The conductive features 55 may comprise, for example conductive lines, conductive vias, conductive pads, metallization patterns, redistribution layers, or the like. In some embodiments, the conductive features 55 include bonding pads 56 formed at the front-side surface (e.g., at or in the top-most dielectric layer) of the interconnect structure 54. Conductive features 55 of the interconnect structure 54 may be electrically connected to the integrated circuit devices and/or the TSVs 52. The conductive features 55 may be formed using a damascene process, a dual damascene process, or another suitable technique. The conductive features 55 may comprise, for example, copper, aluminum, tungsten, ruthenium, cobalt, alloys thereof, combinations thereof, or the like. The dielectric layers may be formed of or comprise dielectric materials such as polymer, silicon nitride, silicon oxide, silicon oxynitride, silicon oxycarbide, silicon carbonitride, the like, combinations thereof, and/or multi-layers thereof. In some embodiments, the dielectric layers may comprise one or more materials such as Phospho-Silicate Glass (PSG), Boro-Silicate Glass (BSG), Boron-Doped Phospho-Silicate Glass (BPSG), undoped Silicate Glass (USG), low-k dielectric materials, or the like. Other materials are possible. In some cases, the dielectric layers may be Inter-Metal Dielectric (IMD) layers. In some embodiments, the top-most dielectric layer (e.g., the exposed dielectric layer) is a “bonding layer” comprising a dielectric material suitable for dielectric-to-dielectric bonding (e.g., direct bonding, fusion bonding, oxide-to-oxide bonding, or the like). For example, the bonding layer may comprise silicon oxide, silicon oxynitride, or the like, though other materials are possible. The interconnect structure 54 shown in FIG. 1 is an example, and an interconnect structure 54 may have additional layers of conductive features, may have different features, or may have a different configuration than shown. In some embodiments, the interconnect structure 54 may comprise a seal ring (not shown).

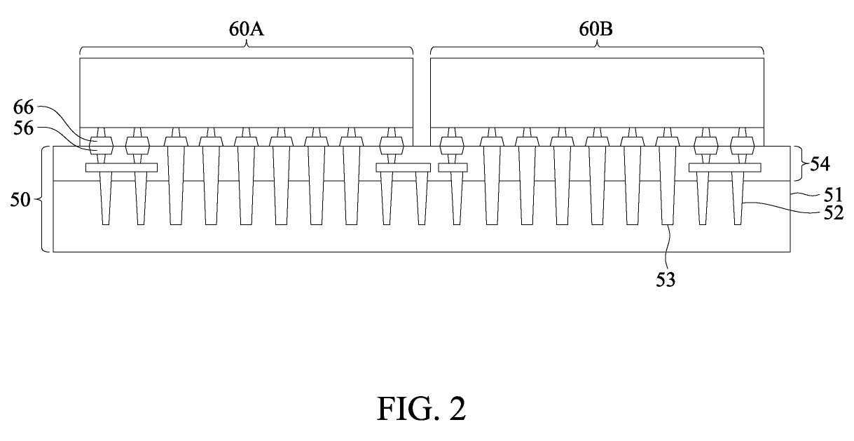

In some embodiments, the TSVs 52 and the thermal vias 53 extend into the substrate 51, as shown in FIG. 1. The TSVs 52 are electrically connected to conductive features 55 of the interconnect structure 54, and may extend into the interconnect structure 54, as shown in FIG. 1. The thermal vias 53 extend partially or fully through the interconnect structure 54. In some embodiments, the thermal vias 53 extend fully through the interconnect structure 54 and have exposed top surfaces. In other embodiments, the thermal vias 53 are covered by bonding pads 56. In other embodiments, conductive features 55 extend between a thermal via 53 and an overlying bonding pad 56 to form a thermally conductive path between the thermal via 53 and the overlying bonding pad 56. In this manner, the thermal vias 53 may provide thermally conductive paths that facilitate transfer of heat away from overlying devices 60A-B (described below for FIG. 2). The TSVs 52 and the thermal vias 53 may be formed of conductive materials, such as those described above for the conductive features 55. The TSVs 52 and the thermal vias 53 may be formed of similar materials or different materials. In some embodiments, the thermal vias 53 may have a larger width than the TSVs 52. The TSVs 52 and the thermal vias 53 may be formed using the same simultaneous process step(s) or using separate (e.g., sequential) process step(s). The thermal vias 53 may be electrically isolated from active and/or passive devices within the devices 60A-B or within the wafer 50. Other arrangements, configurations, shapes, or dimensions of TSVs 52 or thermal vias 53 are possible.

In FIG. 2, devices 60A-B are bonded to the interconnect structure 54 of the wafer 50, in accordance with some embodiments. As an example, FIG. 2 illustrates two devices 60A-B, but in other embodiments more or fewer devices may be present. Device 60A-B may include, for example, a chip, a die, a semiconductor device, an integrated circuit die, a system-on-chip (SoC) device, a system-on-integrated-circuit (SoIC) device, a package, the like, or a combination thereof. In some embodiments, devices 60A-B comprise a logic die (e.g., central processing unit (CPU, xPU), a graphics processing unit (GPU), a system-on-a-chip (SoC), an application processor (AP), microcontroller, etc.), a memory die (e.g., dynamic random access memory (DRAM) die, static random access memory (SRAM) die, a hybrid memory cube (HMC) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), a BaseBand (BB) die, a photonic integrated circuit, a photonic package, a photonic die, the like, or combinations thereof. Other types of devices 60A-B are possible. The devices 60A and 60B may be similar types of devices or may be different types of devices, and may have similar dimensions or different dimensions.

In some embodiments, the devices 60A-B are attached to the wafer 50 using a direct bonding process, such as fusion bonding, dielectric-to-dielectric bonding, and/or metal-to-metal bonding. In accordance with some embodiments, the bonding of the devices 60A-B to the wafer 50 includes pre-treating the bonding surfaces of the devices 60A-B and/or the bonding surfaces of the interconnect structure 54 with a process gas comprising oxygen (O₂) and/or nitrogen (N₂), performing a pre-bonding process to bond the bonding surfaces together, and then performing an annealing process to strengthen the bond. The bonding surfaces of the interconnect structure 54 may comprise, for example, exposed surfaces of the bonding layer of the interconnect structure 54 and exposed surfaces of the bonding pads 56. The bonding surfaces of the devices 60A-B may comprise, for example, exposed surfaces of bonding layers and exposed surfaces of bonding pads 66.

In accordance with some embodiments, during the pre-bonding process, the bonding surfaces of the devices 60A-B are put into physical contact with the bonding surfaces of the interconnect structure 54. Metal bonding pads 66 of the devices 60A-B may be put into physical contact with corresponding bonding pads 56 of the interconnect structure 54. A pressing force may be applied to press the devices 60A-B against the interconnect structure 54. The pre-bonding process may be performed at room temperature (e.g., in the range from about 20 °C to about 25 °C), though a higher temperature may also be used. After the pre-bonding process, an annealing process is performed to bond the devices 60A-B to the interconnect structure 54. Dielectric bonding surfaces of the devices 60A-B are bonded to the bonding layer of the interconnect structure 54 by dielectric-to-dielectric bonds, and metal bonding pads 66 of the devices 60A-B are bonded to bonding pads 56 of the interconnect structure 54 by metal-to-metal bonds. In accordance with some embodiments, the annealing process is performed at a temperature in a range from 150 ° C to 350 ° C. The annealing duration may be in a range from 30 minutes to 60 minutes. Other bonding techniques are possible.

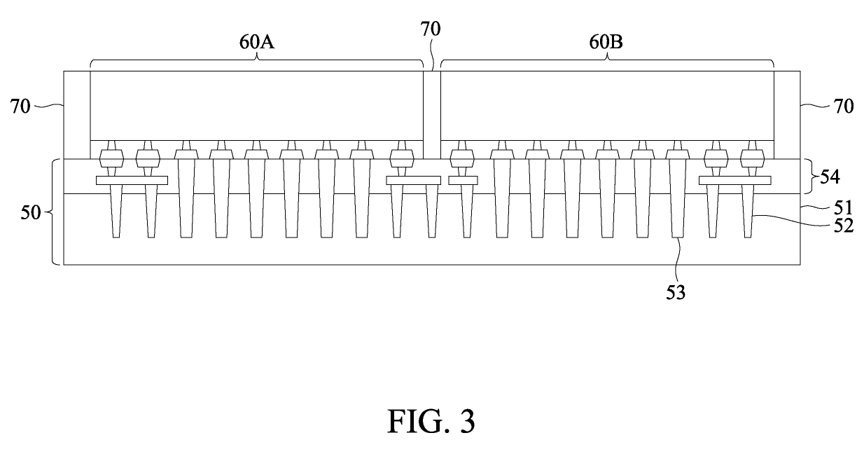

In FIG. 3, a molding material 70 is deposited on the wafer 50 and between the devices 60A-B, in accordance with some embodiments. The molding material 70 may be deposited over the wafer 50, over the devices 60A-B, and between adjacent devices 60A-B (e.g., between neighboring devices 60A and 60B). The molding material 70 may laterally surround each device 60A and 60B. The molding material 70 may comprise a molding compound, an encapsulant, an epoxy, a polymer, a composite material, a silicon oxide filler material, or the like. The molding material 70 may be applied by compression molding, transfer molding, deposition, or the like. The molding material 70 may be applied in liquid or semi-liquid form and then subsequently cured. In some embodiments, a planarization process, such as a Chemical Mechanical Polishing (CMP) process or a grinding process, may be performed to remove excess portions of the molding material 70. In some embodiments, the planarization process exposes the devices 60A-B, and top surfaces of the devices 60A-B and the molding material 70 are substantially level after performing the planarization process.

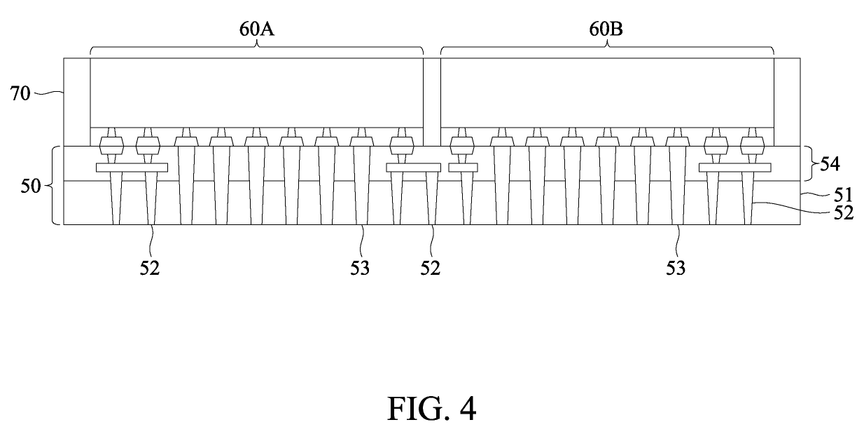

In FIG. 4, the back side of the substrate 51 is thinned to expose the TSVs 52 and the thermal vias 53, in accordance with some embodiments. The substrate 51 may be thinned using a planarization process (e.g., a CMP process and/or a grinding process), an etching process, the like, or a combination thereof. In other embodiments, the thermal vias 53 may be formed after thinning the substrate 51.

In FIG. 5, a support 90 is attached to the front side of the structure and conductive connectors 80 are formed on the back side of the structure, in accordance with some embodiments. The support 90 is a rigid substrate that is attached to provide structural or mechanical stability. The support 90 may comprise one or more materials such as silicon (e.g., a silicon wafer, bulk silicon, or the like), silicon oxide, metal, ceramic, core material, build-up film, the like, or other suitable material(s). In some embodiments, the support 90 may be attached using an adhesive layer (not separately illustrated) or the like. In other embodiments, the support 90 is attached to the devices 60A-B using dielectric-to-dielectric bonding or the like. For example, bonding layers (not separately illustrated) may be formed on the devices 60A-B and on the support 90 and then bonded together using suitable dielectric-to-dielectric bonding techniques. Other attachment techniques are possible. In other embodiments, the support 90 may be attached at a different process step, such as prior to the step shown in FIG. 4, after singulation, or after forming the conductive connectors 80.

In some embodiments, a redistribution structure 58 is formed on the back side of the substrate 51, and then the conductive connectors 80 are formed on or in the redistribution structure 58. The redistribution structure 58 may include one or more metallization layers (e.g., redistribution layers, redistribution lines, or the like) formed in one or more dielectric layers (not individually labeled). Metallization layers of the redistribution structure 58 may be electrically connected to the TSV 52, and some metallization layers may physically contact thermal vias 53. In this manner, some metallization layers are electrically coupled to the devices 60A-B by the TSVs 52 and the interconnect structure 54, and some metallization layers are thermally coupled to the thermal vias 53. The illustrated redistribution structure 58 is an example, and may include more or fewer dielectric layers and/or metallization layers than illustrated. In other embodiments, the thermal vias 53 may extend fully or partially through the redistribution structure 58.

The dielectric layer(s) of the redistribution structure 58 are formed of one or more suitable dielectric materials, such as a polymer, which may be a photosensitive material such as PBO, polyimide, a BCB-based polymer, or the like, which may be patterned using a lithography mask. In other embodiments, the dielectric layer(s) are formed of an oxide such as silicon oxide, PSG, BSG, BPSG; a nitride such as silicon nitride; a combination thereof such as silicon oxynitride; or the like. The dielectric layer(s) may be formed by spin coating, lamination, Chemical Vapor Deposition (CVD), the like, or a combination thereof. After each dielectric layer is formed, it may then be patterned to expose underlying conductive features, e.g. underlying portions of the metallization layer(s). The patterning may be performed using an acceptable process, such as by exposing the dielectric layer to light when it is a photosensitive material, or by etching using, for example, an anisotropic etch. If the dielectric layer is formed of a photosensitive material, it can be developed after the exposure.

The metallization layer(s) include conductive features such as conductive vias and/or conductive lines. The conductive vias extend through the dielectric layer(s), and the conductive lines extend along the dielectric layer(s). As an example to form a metallization layer, a seed layer (not separately illustrated) is formed over the respective underlying features. For example, the seed layer can be formed on a respective dielectric layer and in the openings through the respective dielectric layer, or can be formed on the TSVs 52, the thermal vias 53, and/or the substrate 51. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using a deposition process, such as Physical Vapor Deposition (PVD) or the like. A photoresist is then formed and patterned on the seed layer. The photoresist may be formed by spin coating or the like and may be exposed to light for patterning. The pattern of the photoresist corresponds to the metallization layer. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may include a metal or a metal alloy, such as copper, titanium, tungsten, aluminum, the like, or combinations thereof. Then, the photoresist and portions of the seed layer on which the conductive material are not formed are removed. The photoresist may be removed by an acceptable ashing or stripping process, such as using an oxygen plasma or the like. Once the photoresist is removed, exposed portions of the seed layer are removed, such as by an acceptable etching process, such as by wet or dry etching. The remaining portions of the seed layer and conductive material form the metallization layer. This is an example, and other techniques or materials may be used to form the redistribution structure 58. For example, in some cases, the redistribution structure 58 may comprise other passivation layers or insulating layers.

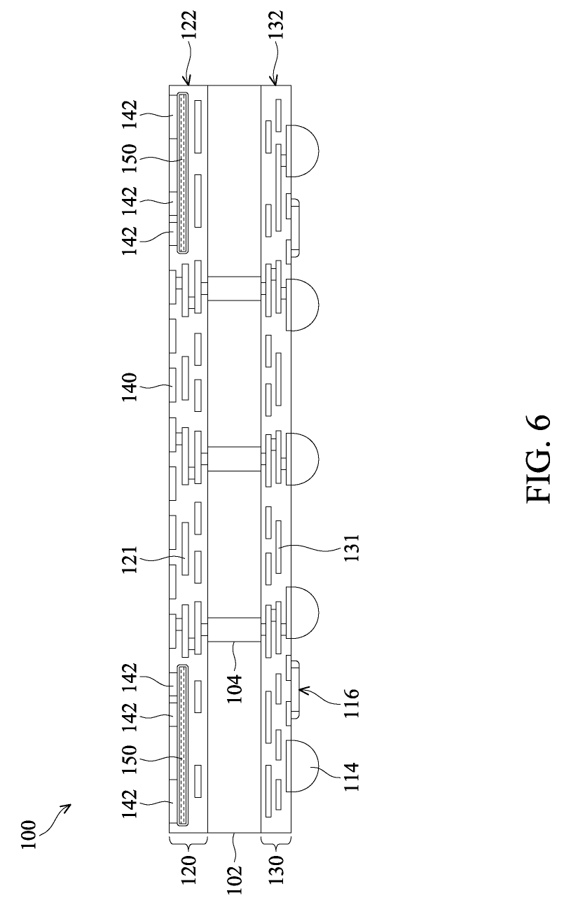

In some embodiments, conductive connectors 80 may be formed on the redistribution structure 58 for attaching the package component 10 to a component or substrate (e.g., the package substrate 100 of FIG. 6). In some embodiments, the conductive connectors 80 optionally include under bump metallurgies (UBMs). The UBMs may have bump portions on and extending along the major surface of the redistribution structure 58, and have via portions extending through the redistribution structure 58 to physically and electrically connect to the metallization layer(s). The UBMs may comprise one or more conductive materials such as metal, such as copper, titanium, tungsten, aluminum, or the like. The UBMs may be formed of the same material(s) as the metallization layer(s). In some embodiments, the UBMs have a different size than the metallization layer(s).

In some embodiments, the conductive connectors 80 comprise connectors, which may be formed on the UBMs (if present). The connectors may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The connectors may include a conductive material such as solder, copper, aluminum, gold, nickel, silver, palladium, tin, the like, or a combination thereof. In some embodiments, the connectors are formed by initially forming a layer of solder through evaporation, electroplating, printing, solder transfer, ball placement, or the like. Once a layer of solder has been formed on the structure, a reflow may be performed in order to shape the material into desired bump shapes. In another embodiment, the connectors comprise metal pillars (such as copper pillars) formed by sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process. In other embodiments, the conductive connectors 80 are metal bonding pads or the like.

In some embodiments, a singulation process is performed to separate the package components 10 formed on the same substrate 51 into individual package components 10. The singulation process may comprise a sawing process, an etching process, or any other suitable singulation process. In this manner, a package component 10 comprising multiple devices 60A-B may be formed. The process described in FIGS. 1-5 for forming package components 10 is an example, and a package component 10 may have a different configuration or may be formed using different process steps than shown. All suitable materials, techniques, or variations thereof are considered within the scope of the present disclosure.

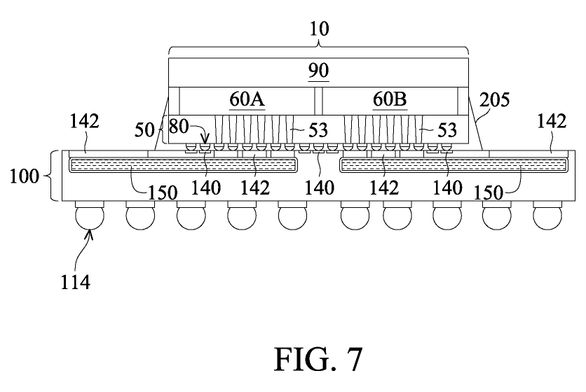

In FIGS. 6 and 7, a package component 10 is attached to a package substrate 100, in accordance with some embodiments. FIG. 6 illustrates a cross-sectional view of a package substrate 100, and FIG. 7 illustrates a cross-sectional view of a package component 10 attached to a package substrate 100, in accordance with some embodiments. For clarity, simplified drawings of a package component 10 and a package substrate 100 are shown in FIG. 7 and subsequent figures. The package substrate 100 may be any suitable substrate or component, such as a device die, a redistribution structure, an interposer, a wafer, a semiconductor substrate, a panel, a core substrate, a printed circuit board (PCB), a motherboard, a main board, an interconnect substrate, or the like.

In some embodiments, the package substrate 100 may include a core substrate 102. The core substrate 102 may comprise one or more materials such as Ajinomoto build-up film (ABF), a pre-impregnated composite fiber (“prepreg”) material, an epoxy, a molding compound, an epoxy molding compound, fiberglass-reinforced resin materials, printed circuit board (PCB) materials, silica filler, polymer materials, polyimide materials, paper, glass fiber, non-woven glass fabric, glass, ceramic, other build-up materials, other laminates, the like, or combinations thereof. In some embodiments, the core substrate 102 may be a double-sided copper-clad laminate (CCL) substrate or the like.

In some embodiments, the package substrate 100 includes a front-side routing structure 120 on the front side of the core substrate 102 and a back-side routing structure 130 on the back side of the core substrate 102. The routing structures 120/130 comprise a plurality of routing layers, which may include conductive lines, conductive vias, conductive pads, metallization patterns, redistribution layers, or the like. For example, the front-side routing structure 120 comprises a plurality of routing layers 121 in a plurality of insulating layers 122 (not individually illustrated), and the back-side routing structure 130 comprises a plurality of routing layers 131 in a plurality of insulating layers 132 (not individually illustrated). The routing layers 121 of the front-side routing structure 120 may comprise bonding pads 140 at the front-side surface (e.g., the top surface) of the front-side routing structure 120. The bonding pads 140 may allow for physical and electrical connection to a package component, such as package component 10 described previously. In some cases, the bonding pads 140 may include conductive pads, conductive pillars, solder bumps, UBMs, or the like. In some embodiments, the routing layers 121/131 may comprise one or more layers of copper, nickel, aluminum, other conductive materials, the like, or a combination thereof. In some embodiments, the insulating layers 122/132 may include materials such as build-up material, ABF, prepreg material, laminate material, oxide, nitride, polymer, or other material(s) similar to those described above for the core substrate 102. Other materials are possible.

In some embodiments, the front-side routing structure 120 includes thermal pads 142 at the front-side surface of the front-side routing structure 120. The thermal pads 142 allow for physical connection to a package component (e.g., package component 10), and are thermally coupled to the package component to transfer heat away from the package component. For example, as described in greater detail below, the thermal pads 142 may be thermally coupled to thermal vias 53 of a package component 10 and may dissipate heat away from the devices 60A-B. In some embodiments, the thermal pads 142 may be similar to the bonding pads 140, and may be formed using similar techniques or the same process steps. The thermal pads 142 may be formed of one or more thermally conductive materials, such as metal. The materials of the bonding pads 140 and the thermal pads 142 may be similar or different. In some embodiments, the thermal pads 142 and the bonding pads 140 have a similar thickness. In other embodiments, the thermal pads 142 are thicker than the bonding pads 140, which may improve heat dissipation. In some embodiments, the thermal pads 142 have a thickness in the range of about 10 µm to about 550 µm, though other thicknesses are possible.

In some embodiments, the front-side routing structure 120 includes heat pipes 150 or the like. In other embodiments, other thermal dissipation structures such as vapor chambers, heat spreaders, or the like may be used instead of or in addition to heat pipes. Accordingly, in some cases, “heat pipes 150” as used herein may represent all such suitable variations or combinations of thermal dissipation structures. The heat pipes 150 may physically contact the thermal pads 142, such that the heat pipes 150 can transfer heat from relatively hot thermal pads 142 to relatively cool thermal pads 142, thus dissipating heat. A heat pipe 150 may extend underneath one or more thermal pads 142 and may be thermally coupled to the overlying thermal pads 142. For example, forming the package substrate 100 may include placing one or more heat pipes 150 on a first insulating layer 122 and then forming a second insulating layer 122 over the heat pipes 150 and the first insulating layer 122. In some cases, a heat pipe 150 may extend to a sidewall (or near a sidewall) of the package substrate 100 such that a side surface of the heat pipe 150 is exposed. A side of a heat pipe 150 may be recessed from a sidewall of the package substrate 100, approximately coterminous with a sidewall of the package substrate 100, or protrude from a sidewall of the package substrate 100.

In some embodiments, the heat pipes 150 may be thin enough to be embedded within one or more insulating layers 122 of the front-side routing structure 120. For example, a thickness of a heat pipe 150 may be greater than, about the same as, or less than a thickness of an insulating layer 122. Accordingly, a thickness of a heat pipe 150 may be less than a thickness of the front-side routing structure 120. In some embodiments, a heat pipe 150 may have a thickness in the range of about 0.3 mm to about 1 mm, though other thicknesses are possible. In some cases, forming thin heat pipes 150 allows the heat pipes 150 to be incorporated into the package substrate 100, which can allow for more efficient heat dissipation within a package and allow for smaller package dimensions. In some embodiments, a heat pipe 150 may be sandwiched between two insulating layers 122. Different heat pipes 150 may be at different levels within the front-side routing structure 120 (e.g., within different insulating layers 122), and different heat pipes 150 may have different dimensions (e.g., thicknesses, lengths, shapes, etc.). In other embodiments, heat pipes 150 may be present in the core substrate 102 and/or in the back-side routing structure 130.

In some embodiments, the package substrate 100 includes through vias 104 extending through the core substrate 102 that electrically connect the front-side routing structure 120 to the back-side routing structure 130. In this manner, the routing structures 120/130 and the through vias 104 provide additional electrical routing and interconnection. In some embodiments, the through vias 104 may be filled with a filler material (not illustrated). In some embodiments, conductive connectors 114 are formed on the back-side routing structure 130. The conductive connectors 114 may be similar to the conductive connectors 80 described previously, and may include UBMs or the like. In some embodiments, one or more optional passive devices 116 may be connected to the back-side routing structure 130. The passive devices 116 may be surface mount devices (SMD), voltage regulators, chiplets, semiconductor devices, capacitors, or other suitable passive devices. In other embodiments, passive devices 116 are not present. The package substrate 100 of FIG. 6 is intended as an illustrative example, and another number, arrangement, or configuration of routing structures 120/130, heat pipes 150, thermal pads 142, through vias 104, or other features are possible.

In FIG. 7, the package component 10 is bonded to the package substrate 100, in accordance with some embodiments. The package component 10 may be bonded to the package substrate 100, for example, by aligning the conductive connectors 80 with corresponding bonding pads 140 and thermal pads 142 of the package substrate 100. The conductive connectors 80 are then placed into contact with the corresponding bonding pads 140 and thermal pads 142 and a reflow process may be performed to bond the conductive connectors 80 to the corresponding bonding pads 140 and thermal pads 142 of the package substrate 100. In this manner, the package component 10 may be physically and electrically connected to the package substrate 100. The TSVs 52 (see FIG. 5) of the package component 10 are physically and electrically coupled to the bonding pads 140 of the package substrate 100 by conductive connectors 80 of the package component 10, and thermal vias 53 of the package component 10 are physically and thermally coupled to thermal pads 142 of the package substrate 100 by conductive connectors 80 of the package component 10. In other embodiments, the package component 10 may be bonded to the package substrate 100 using direct bonding, such as dielectric-to-dielectric bonding and/or metal-to-metal bonding.

Still referring to FIG. 7, an optional underfill 205 may be deposited between the package component 10 and the package substrate 100, in accordance with some embodiments. The underfill 205 may surround the conductive connectors 80. In some cases, the underfill 205 is cured using a thermal process, an ultraviolet (UV) process, or the like. In other embodiments, an underfill 205 is not formed.

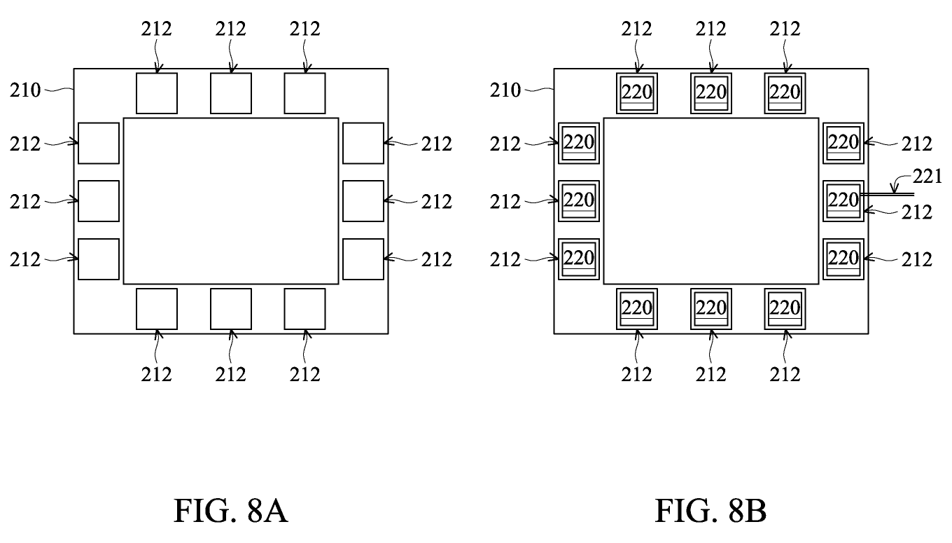

FIGS. 8A and 8B illustrate plan views of a support structure 210 comprising thermoelectric coolers (TECs) 220, in accordance with some embodiments. FIG. 8A illustrates a support structure 210 without TECs 220, and FIG. 8B illustrates a support structure 210 incorporating TECs 220. The support structures 210 and TECs 220 of FIGS. 8A-8B are intended as illustrative examples, and other numbers, shapes, dimensions, arrangements, or configurations are possible.

The support structure 210 may be a rigid structure that is attached to the package substrate 100 to provide structural support, reduce warping, and dissipate heat. As shown in FIGS. 8A-8B, the support structure 210 may be a ring-like structure, such as a stiffener ring or the like. The support structure 210 may comprise one or more suitable materials such as a metal, a ceramic, or the like. In some embodiments, the support structure 210 comprises one or more openings 212 that extend partially or fully through the support structure 210. TECs 220 are subsequently placed in corresponding openings 212, described in greater detail below. Each opening 212 may be laterally surrounded by material of the support structure 210. In other embodiments, the material of the support structure 210 may not fully encircle an opening 212. Accordingly, the dimensions (e.g., width and/or length) of an opening 212 may be larger than the dimensions of its corresponding TEC 220.

In FIG. 8B, TECs 220 have been placed in the openings 212 of the support structure 210, in accordance with some embodiments. Each TEC 220 may be placed in a corresponding opening 212. In some cases, multiple TECs 220 may be placed in the same opening 212. In some embodiments, a TEC 220 may physically contact the support structure 210 (e.g., at one or more sidewalls of the opening 212). In some embodiments, a TEC 220 may be separated from the sidewalls of the opening 212 by a gap that partially or fully encircles the TEC 220. In some embodiments, the gap may be partially or fully filled by a suitable filling material (not illustrated) such as an adhesive, an underfill, a molding material, an epoxy, the like, or a combination thereof. The filling material may act as a seal, a moisture barrier, or the like that protects the TECs 220 from moisture. In other embodiments, no material is deposited in the gap between a TEC 220 and a sidewall of the opening 212. In some cases, the filling material may surround, encircle, or encapsulate the TECs 220.

In some embodiments, the TECs 220 comprise alternating regions of an n-type material and a p-type material (not separately illustrated in FIGS. 8A-8B). The alternating regions of n-type material and p-type material may be electrically coupled in series. The n-type material and the p-type material may comprise the same material with different doping. For example, the n-type material and the p-type material may comprise doped bismuth telluride, though other materials are possible. In other cases, the n-type material and the p-type material may comprise different materials or different combinations of materials.

When operated as a heat transfer device (e.g., a cooling device), an electrical current flowing through a TEC 220 facilitates the transfer of heat from one side of the TEC 220 to the opposite side of the TEC 220 (e.g., by the Peltier effect). Accordingly, the TECs 220 may be connected to a current source or the like by one or more connectors 221, such as wires or the like. In some embodiments, the connector(s) 221 may pass through opening(s) in the sidewalls of the support structure 210. In this manner, a TEC 220 incorporated within the support structure 210 may be able to efficiently transfer heat away from the package component 10 and/or the package substrate 100, described in greater detail below. In some cases, a TEC 220 may also be operated as a thermoelectric generator that supplies electrical power into a connector 221 using the Seebeck effect.

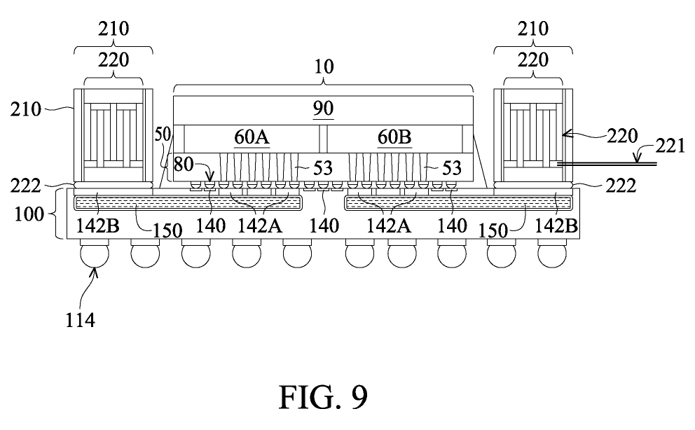

Turning to FIG. 9, the support structure 210 and the TECs 220 are attached to the package substrate 100, in accordance with some embodiments. The TECs 220 may be attached to the support structure 210 before attachment to the package substrate 100, in some embodiments. In other embodiments, the support structure 210 may be attached to the package substrate 100 first, and then the TECs 220 may be placed in the openings 212 of the support structure 210. A height of a TEC 220 may be greater than, about the same as, or smaller than a height of the support structure 210. Accordingly, a top surface of the support structure 210 may be higher than, approximately level with, or lower than a top surface of a TEC 220. The TECs 220 shown in FIG. 9 are illustrative examples, and may have other dimensions or configurations than shown. In FIG. 9 and some subsequent figures, the thermal pads 142 that are underneath the package component 10 and/or are attached to conductive connectors 80 are indicated as thermal pads 142A, and the thermal pads 142 that are underneath the TECs 220 and/or are attached to the TECs 220 are indicated as thermal pads 142B. In some cases, one or more thermal pads 142 may not physically contact any heat pipes 150.

In some embodiments, the support structure 210 and/or the TECs 220 are attached to the package substrate 100 using an adhesive 222, which may be an adhesive thermal interface material (TIM) or the like. In some embodiments, the support structure 210 and/or the TECs 220 are attached to thermal pads 142B of the package substrate 100. Attaching the TECs 220 to thermal pads 142B using an adhesive TIM 222 can facilitate the transfer of heat from the thermal pads 142B into the overlying TECs 220 and away from the package substrate 100. In some embodiments, each TEC 220 overlies a corresponding thermal pad 142B. In some cases, portions of the support structure 210 and/or TECs 220 do not extend over thermal pads 142B. In other embodiments, one or more TECs 220 are not disposed over a thermal pad 142B. A thermal pad 142B may have dimensions (e.g., a length, width, or area) that is greater than, about the same as, or smaller than its overlying TEC 220. After attachment, a top surface of the support structure 210 may be higher than, approximately level with, or lower than a top surface of the package component 10.

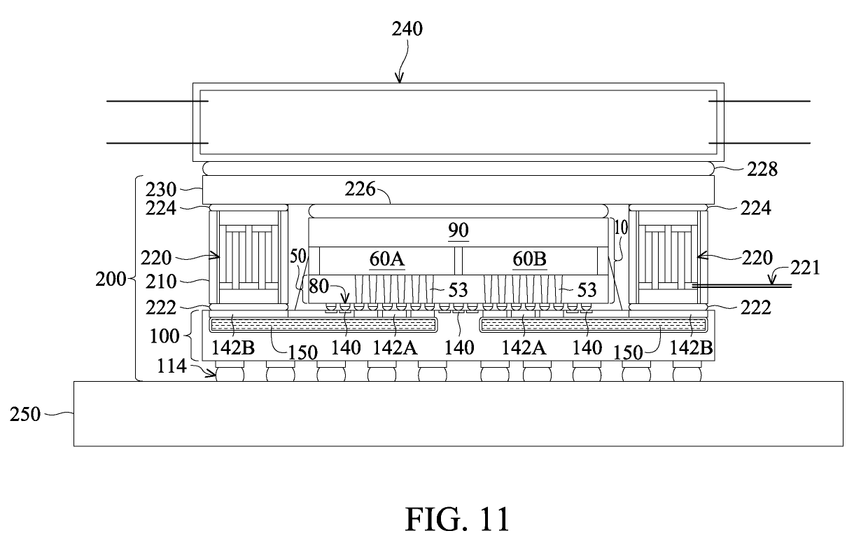

In FIG. 10, a heat spreader 230 is attached to form a package 200, in accordance with some embodiments. The heat spreader 230 may be formed of one or more thermally conductive materials, such as metal. The heat spreader 230 is attached to the support structure 210, the TECs 220, and the package component 10, in some embodiments. For example, the heat spreader 230 may be attached to the support structure 210 and/or the TECs 220 by an adhesive TIM 224, and the heat spreader 230 may be attached to the package component 10 by an adhesive TIM 226. The heat spreader 230 dissipates heat from the TECs 220 and the package component 10, distributes the heat over a larger area, and also may transfer heat to an attached cooling system such as cooling system 240, described below for FIG. 11. In some cases, the heat spreader 230 may be considered a lid, a heat sink, or the like.

In FIG. 11, a cooling system 240 is attached to the package 200, in accordance with some embodiments. The cooling system 240 is attached to the heat spreader 230 of the package 200 by an adhesive TIM 228 or the like. The cooling system 240 receives heat from the heat spreader 230 and transfers the heat away from the package 200, facilitating cooling of the package 200. The cooling system 240 may comprise, for example, a liquid cooling system, an air cooling system, a vapor chamber, a heat pipe, a cooling fan, the like, or a combination thereof. The cooling system 240 may also comprise fins, heat sinks, or other features (not pictured) that can facilitate heat transfer. The cooling system 240 is schematically illustrated in FIG. 11 as a liquid cooling system. For example, the cooling system 240 may comprise a liquid chamber, an inlet, and an outlet. Liquid is flowed into the liquid chamber from the inlet and flows out of the liquid chamber through the outlet. The liquid absorbs heat generated by the package 200 and transports it away from the package 200, facilitating cooling of the package 200. In some embodiments, the flow speed of the liquid may be controlled, which may control the amount of heat dissipation provided by the cooling system 240.

In some embodiments, the package 200 may be attached to an external substrate 250. For example, the conductive connectors 114 of the package 200 may be bonded to the external substrate 250 to make physical and electrical connections between the package 200 and the external substrate 250. The external substrate 250 may be any suitable substrate or component, such as a device die, a redistribution structure, an interposer, a wafer, a core substrate, a printed circuit board (PCB), a motherboard, a main board, a substrate similar to the package substrate 100, or the like. The external substrate 250 may or may not comprise active devices and/or passive devices. The external substrate 250 may comprise conductive features such as conductive lines, vias, or pads to make electrical interconnections within the external substrate 250 and to make electrical connections to external packages or external components attached to the external substrate 250, such as the package 200. In some cases, the structure shown in FIG. 11 may be considered a package structure or the like. The structure shown in FIG. 11 is an example, and other types, configurations, or arrangements of features are possible.

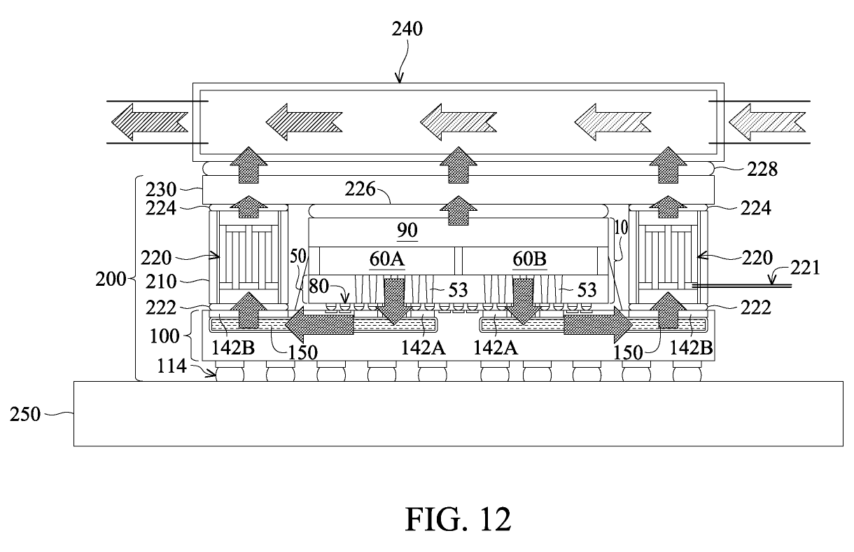

The techniques and structures herein can allow for improved heat dissipation and improved thermal performance of a package. For example, FIG. 12 illustrates a package 200 similar to that shown in FIG. 11, but with arrows that represent heat flow. The arrows indicate some heat flow paths (e.g., heat transfer paths) for explanatory purposes, and other heat flow paths are possible. The thermal vias 53 of the package component 10 provide thermally conductive paths that allow heat to flow away from the devices 60A-B toward the conductive connectors 80. Heat is then able to flow through the conductive connectors 80 and into thermal pads 142A of the package substrate 100. The thermal vias 53 can also reduce heat accumulation in the wafer 50 by facilitating the transfer of heat from the wafer 50 to the package substrate 100. In this manner, the thermal vias 53 facilitate dissipation of heat in the package component 10. Additionally, heat may also flow from the devices 60A-B through the support 90 and into the heat spreader 230. Thus, multiple thermal paths for heat dissipation from the devices 60A-B are provided, which can improve the thermal performance of the package component 10.

The thermal pads 142A thermally couples the thermal vias 53 to the heat pipes 150 and thus allows for more efficient transfer of heat from the package component 10 into the heat pipes 150. The heat pipes 150 of the package substrate 100 transfer heat away from thermal pads 142A underneath the package component 10 to thermal pads 142B underneath the TECs 220. The heat pipes 150 also may dissipate heat by transferring heat to the edges of the package substrate 100. The thermal pads 142B thermally couples the TECs 220 to the heat pipes 150 and thus allows for more efficient transfer of heat from the heat pipes 150 into the TECs 220.

The TECs 220 may be operated to transfer heat from the lower portions of the TECs 220 to upper portions of the TECs 220 (e.g., using the Peltier effect). Heat may then flow from the upper portions of the TECs 220 to the heat spreader 230. The heat spreader 230 distributes and dissipates heat and allows heat to be absorbed by the cooling system 240. In this manner, the heat generated by the package 200 may be efficiently dissipated using a combination of heat dissipation features including thermal vias 53, thermal pads 142, heat pipes 150, TECs 220, a heat spreader 230, and a cooling system 240. In other embodiments, other heat dissipation features may be used instead of or in addition to the described heat dissipation features. In other embodiments, some of the described heat dissipation features may not be present.

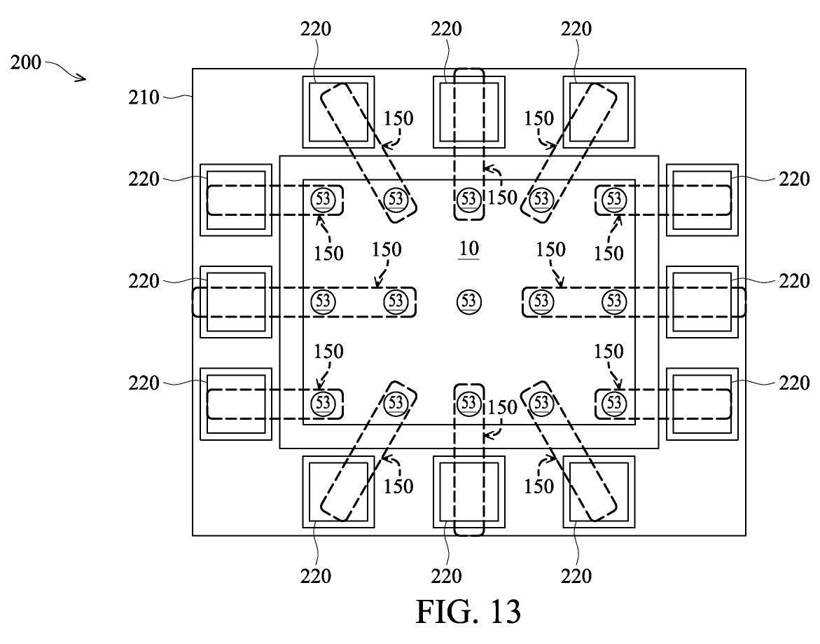

The arrangement or configuration of the thermal vias 53, thermal pads 142, heat pipes 150, and/or TECs 220 may be suited for efficient heat dissipation for a particular application (e.g., a particular package 200 configuration). Accordingly, FIGS. 13-16 illustrate schematic plan views of example arrangements and configurations of thermal vias 53, heat pipes 150, and TECs 220, in accordance with some embodiments. The TECs 220 are placed within openings 212 of a support structure 210, and the support structure 210 surrounds a package component 10, similar to the package 200 of FIG. 11. The embodiments of FIGS. 13-16 are intended as illustrative examples, and other arrangements or configurations are possible. All suitable variations should be considered within the scope of the present disclosure. For example, a different number, arrangement, or configuration of features may be used in other embodiments. For clarity, some features of a package 200 are not illustrated in FIGS. 13-16. For example, thermal pads 142 are not illustrated in FIGS. 13-16, though thermal pads 142A may be present between heat pipes 150 and thermal vias 53 and thermal pads 142B may be present between heat pipes 150 and TECs 220. Other features may also not be illustrated in FIGS. 13-16, such as devices 60A-B, TSVs 52, conductive connectors 80, and bonding pads 140.

Turning to FIG. 13, a schematic plan view of a package 200 having an approximately uniform distribution of thermal vias 53 is shown, in accordance with some embodiments. In FIG. 13, the thermal vias 53 of the package component 10 are in array-like arrangement. In some embodiments, the thermal vias 53 may be arranged in a rectangular array having uniform spacing along each row and/or column of the array. In some cases, forming the thermal vias 53 in an approximately uniform arrangement can provide more uniform heat dissipation across the wafer 50. FIG. 13 illustrates most of the thermal vias 53 as being thermally coupled to an underlying heat pipe 150. In other embodiments, all of the thermal vias 53 are thermally coupled to an underlying heat pipe 150. As shown in FIG. 13, heat pipe 150 may be thermally coupled more than one thermal via 53. The heat pipes 150 may have a roughly radial arrangement similar to that shown in FIG. 13 to transfer heat laterally away from the package component 10. In some embodiments, a heat pipe 150 may extend to an edge of the package 200 and may have an exposed surface to facilitate heat dissipation. Each heat pipe 150 is thermally coupled to at least one TEC 220, in some embodiments. As shown in FIG. 13, in some embodiments the TECs 220 may be in a ring-like arrangement around the package component 10. The TECs 220 may be approximately evenly spaced or may have any other suitable spacing or arrangement. In some cases, a more uniform distribution of TECs 220 may allow for more uniform transfer of heat into the overlying heat spreader 230. In this manner, the distribution of thermal vias 53 and/or TECs 220 may be configured to provide more efficient or more uniform heat dissipation from the package component 10 and/or to provide more efficient or more uniform heat transfer within the package 200.

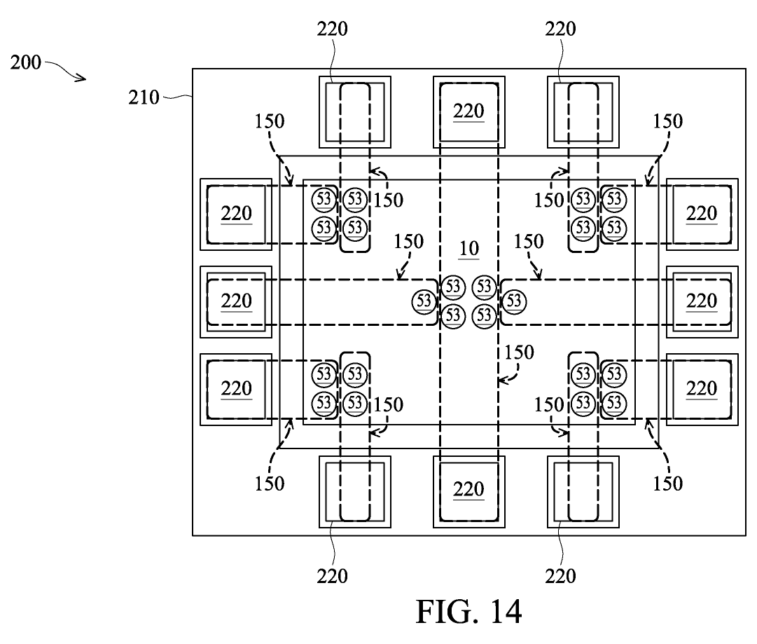

FIG. 14 illustrates a package 200 having a nonuniform distribution of thermal vias 53, in accordance with some embodiments. In some embodiments, the density of thermal vias 53 may be greater near regions of greater heat generation within the package component 10. Relatively hotter regions of the package component 10 may have a greater average density of thermal vias 53, and relatively cooler regions of the package component 10 may have a smaller average density of thermal vias 53, in some cases. For example, in some embodiments, thermal vias 53 may be clustered near relatively hotter regions of the package component 10, such as near “hot spots” of the package component 10. By configuring the distribution of thermal vias 53 according to the distribution of heat generation of the package component 10, heat can be more efficiently dissipated from the package component 10. Additionally, the layout of the features within the package 200 may be more efficient and more flexible. In some embodiments, the distribution of TECs 220 may also be configured to provide more efficient heat dissipation. For example, in some cases, the locations of the thermal vias 53 and/or the TECs 220 may be chosen to minimize the dimensions of the corresponding heat pipes 150. Other arrangements or rationales are possible. In this manner, the distribution of thermal vias 53 and/or TECs 220 may be configured to provide more efficient heat dissipation from the package component 10 and/or to provide more efficient heat transfer within the package 200.

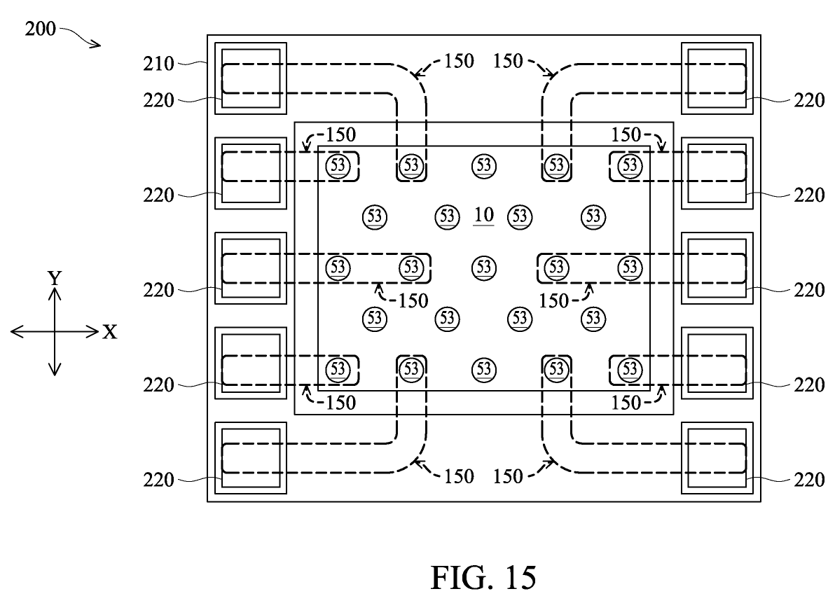

In FIG. 15, the TECs 220 are mostly located along two opposite sides of the support structure 210, with fewer TECs 220 along the other two opposite sides of the support structure 210. FIG. 15 also indicates an X-direction and a Y-direction used for reference in the following discussion. In some embodiments, most or all of the TECs 220 are arranged along a single direction. In other words, most or all of the TECs 220 are arranged along the sides of the support structure 210 that are parallel to a direction, with the sides of the support structure 210 that are not parallel to this direction having fewer TECs 220. For example, most of the TECs 220 in FIG. 15 are arranged along the sides of the support structure 210 that are parallel to the Y-direction, with TECs 220 only present at the ends (e.g., the corners) of the sides parallel to the X-direction. Accordingly, in some embodiments, the sides of the support structure 210 that are parallel to a first direction may have a smaller number or a smaller density of TECs 220 than the sides of the support structure 210 that are parallel to a second direction. In some cases, some TECs 220 may be positioned near a side that is not adjacent to their corresponding thermal vias 53. Accordingly, some heat pipes 150 may be elongated and/or curved to extend between some TECs 220 and their corresponding thermal vias 53. For example, a heat pipe 150 in a plan view may have a linear and/or curved path. The number, arrangement, shape, or configuration of TECs 220, thermal vias 53, or heat pipes 150 may be different than shown, and the sides of the package 200 may have different relative lengths than shown.

Because openings 212 are formed in the support structure 210 to receive TECs 220, arranging most of the TECs on opposite sides of the support structure 210 can reduce warping of the package 200. For example, because the package 200 of FIG. 15 is longer in the X-direction than in the Y-direction, having the TECs 220 mostly arranged along the sides parallel to the Y-direction can reduce warping along the X-direction. In this manner, arranging TECs 220 mostly along opposite sides can reduce warping of the package 200, in some cases. In some cases, the reduction in warping may be most pronounced for a rectangular package, with the TECs 220 arranged along the shorter sides of the support structure 210.

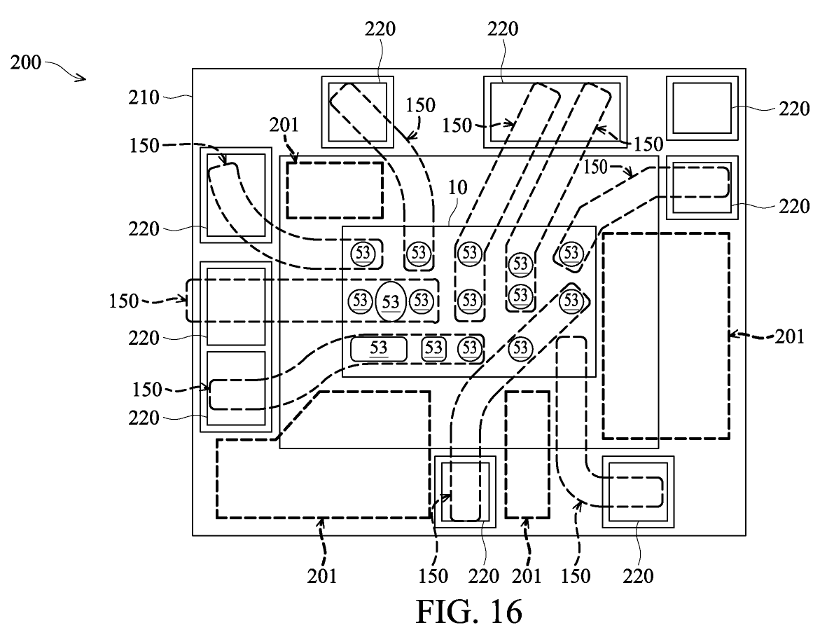

Any suitable number, arrangement, or configuration of TECs 220, thermal vias 53, or heat pipes 150 may be used in other embodiments. For example, FIG. 16 illustrates an embodiment of a package 200 having a non-limiting arrangement of TECs 220, thermal vias 53, and heat pipes 150 with various characteristics. In some embodiments, some heat pipes 150 may be elongated and/or curved to allow for open areas 201 in the package substrate 100. In other words, the shapes or paths of some heat pipes 150 may be chosen to avoid certain regions in the package substrate 100. The arrangement of thermal vias 53 and/or TECs 220 may also be chosen to form open areas 201. In this manner, other features or structures may be formed in the open areas 201, allowing for flexible design. The features or structures may include, for example, bonding pads 140, routing layers 121, embedded passive devices or chiplets, the like, or other features or structures.

In some embodiments, thermal vias 53 may not be formed over a heat pipe 150. Different thermal vias 53 in the same package component 10 may have different sizes or shapes. Different heat pipes 150 in the same package substrate 100 may have different sizes or shapes. In some cases, two or more TECs 220 may be placed within the same opening 212. In some cases, two or more heat pipes 150 may be thermally coupled to (e.g., underlie) the same TEC 220. In some embodiments, a single heat pipe 150 may be thermally coupled to (e.g., underlie) two or more TECs 220. In some embodiments, a heat pipe 150 may protrude beyond a sidewall of the support structure 210. In this manner, the techniques described herein allow for efficient and flexible design of heat dissipation for a package.

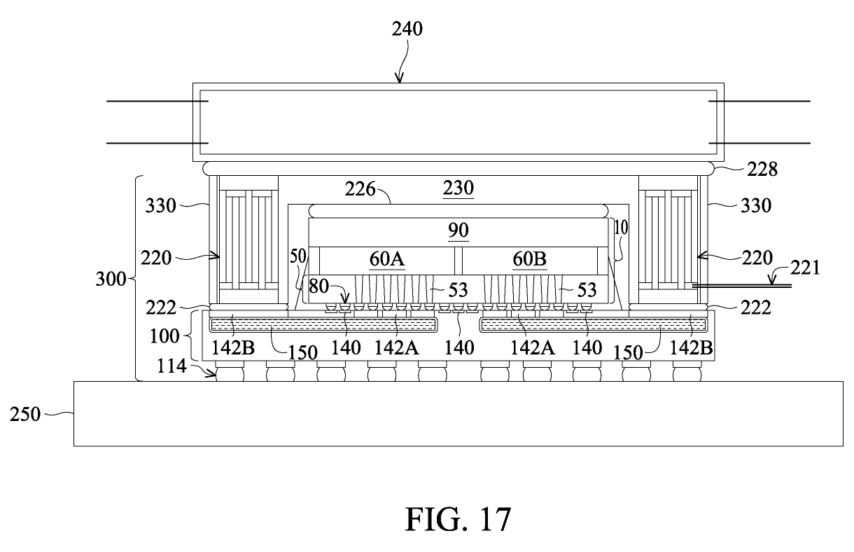

FIG. 17 illustrates a package 300, in accordance with some embodiments. The package 300 is similar to the package 200 of FIG. 11, except that a lid 330 is used rather than a heat spreader 230 and a support structure 210. In some cases, the lid 330 may be considered a combination of a heat spreader and a support structure in a single unit. In this manner, material cost and manufacturing may be reduced. The lid 330 may be attached to the package substrate 100 and the package component 10 using an adhesive TIM 222/226 or the like. In some cases, using a lid 330 rather than a heat spreader and a support structure may reduce the amount of adhesive TIM used. Similar to the support structure 210, TECs 220 may be placed within openings in the lid 330. In some cases, installing TECS 220 in the lid 330 rather than in a support structure may allow the TECs 220 to be closer to the cooling system 240, which can improve heat dissipation. For example, the heat may be more directly transported into the cooling system 240 rather than being transported through a heat spreader, reducing the number of interfaces in the heat transfer path. In this manner, the use of a lid 330 as described herein can reduce manufacturing cost and improve thermal performance.

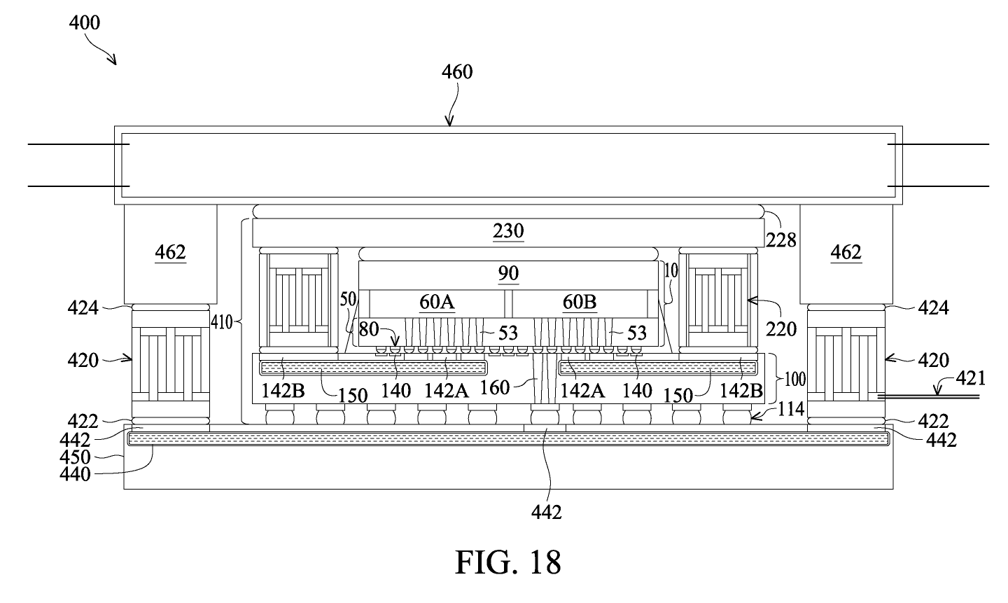

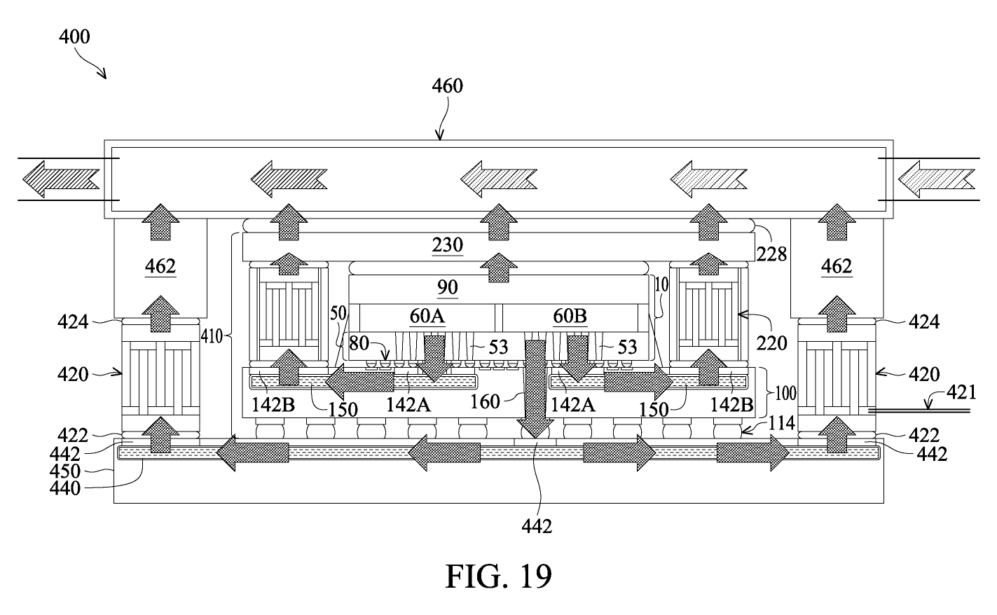

FIGS. 18-19 illustrate a package structure 400, in accordance with some embodiments. The package structure 400 may be similar to the structure shown in FIG. 11, except that the package 410 includes thermal vias 160 in the package substrate 100, additional TECs 420 are used to transfer heat from the external substrate 450 to the cooling system 460, and the external substrate 450 includes thermal pads 442 and heat pipes 440.

The package 410 is similar to the package 200 described for FIG. 11, except that the package substrate 100 includes thermal vias 160 that extend through the package substrate 100. The thermal vias 160 may extend from a top surface of the package substrate 100 to conductive connectors 114 of the package 410 to facilitate the transfer of heat away from the package component 10 and through the package substrate 100. In other embodiments, the thermal vias 160 may extend from thermal pads 142 in the package substrate 100 to the conductive connectors 114. The external substrate 450 may be similar to the external substrate 250 described for FIG. 11, except that heat pipes 440 and thermal pads 442 are formed in the external substrate 450. Conductive connectors 114 underlying thermal vias 160 may be bonded to the thermal pads 442 to allow efficient heat transfer from the package 410 to the external substrate 450. The thermal pads 442 may be formed on heat pipes 440 or the like within the external substrate 450.

In some embodiments, one or more TECs 420 may be attached to thermal pads 442 of the external substrate 450. The TECs 420 may be attached using an adhesive TIM 422 or the like. The TECs 420 may be electrically connected (e.g., using connectors 421) to transfer heat away from underlying thermal pads 442 using the Peltier effect during operation. In some embodiments, a cooling system 460 is attached to the package 410 and the TECs 420 using an adhesive TIM 228/424 or the like. The cooling system 460 may be similar to the cooling system 240 described for FIG. 11, except that the cooling system 460 comprises a heat spreader 462. The heat spreader 462 may be attached to the TECs 420 using the adhesive TIM 424. In this manner, the heat may be transferred from the TECs 420 to the cooling system 460 through the heat spreader 462. In other embodiments, the heat spreader 462 is not present and the TECs 420 are attached to the cooling system 460. In some embodiments, the heat spreader 462 may comprise metal pins, fixtures, supports, or the like of the cooling system 460.

The techniques and structures herein can allow for improved heat dissipation and improved thermal performance of a package. For example, FIG. 19 illustrates a package structure 400 similar to that shown in FIG. 18, but with arrows that represent heat flow. The arrows indicate some heat flow paths (e.g., heat transfer paths) for explanatory purposes, and other heat flow paths are possible. Some heat flow paths may be similar to those described previously for FIG. 12. For example, heat may be transferred through thermal vias 53 and thermal pads 142 to heat pipes 150 of the package substrate 100, and then through TECs 220 to a heat spreader 230 and into the cooling system 460. Additionally, heat may be transferred through the thermal vias 53 to thermal vias 160. Heat may then be transferred to thermal pads 442 of the external substrate 450, into heat pipes 440 of the external substrate 450, and then through other thermal pads 442 into TECs 420. The heat may be transferred from the TECs 420 into the cooling system 460, where it is transferred away from the package structure 400. Thus, multiple thermal paths for heat dissipation from the devices 60A-B are provided, which can improve the thermal performance of the package 200.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments described herein may achieve advantages. Various thermal structures and combinations of thermal structures are described that can improve the thermal performance of a device or package. For example, forming thermal vias in a package component can facilitate heat dissipation away from a bottom die of the package component. Forming thermal pads and thin heat pipes in a package substrate can efficiently transport heat away from the package component. The heat may be transferred to thermoelectric coolers (TECs) incorporated within a support ring. In this manner, heat can efficiently be transferred from the package substrate toward a cooling system, such as a liquid cooling system. Forming TECs within the support ring can reduce package size, improve heat transfer, and allow for flexible design. For example, the techniques described herein allow for a heat transfer path that can spread heat generated from the package component through the package substrate to a heat spreader, and then allows the heat to be dissipated by an active cooling system (e.g., air or liquid cooling or the like). The arrangement, distribution, or configuration of the thermal vias, heat pipes, and TECs may be adjustable for better hot spot control and warpage control. Additionally, the techniques described herein can be extended to an external substrate (e.g., a PCB structure) to enhance the overall cooling performance for the package. In this manner, thermal performance, manufacturing cost, reliability, and yield of a package component or a package may be improved.

In some embodiments, a method includes forming a package component, including forming a thermal via extending through a substrate; and bonding a die to the thermal via; attaching the thermal via of the package component to a first conductive pad of a package substrate, wherein the package substrate includes a heat pipe underneath the first conductive pad; and attaching a support structure to a second conductive pad of the package substrate, wherein the heat pipe is underneath the second conductive pad, wherein the support structure includes a first thermoelectric cooler (TEC). In an embodiment, the thermal via is attached to the first conductive pad by a solder bump. In an embodiment, the heat pipe has a thickness in the range of 0.3 mm to 1 mm. In an embodiment, the first TEC is attached to the second conductive pad by a thermal interface material (TIM). In an embodiment, the heat pipe has a curved path from the first conductive pad to the second conductive pad. In an embodiment, the support structure includes a second TEC, wherein the second TEC is on an opposite side of the package component from the first TEC. In an embodiment, the method includes attaching a heat spreader to the package component and to the support structure. In an embodiment, the method includes attaching a liquid cooling system to the heat spreader.

In an embodiment, a method includes forming a package substrate, including forming a first thermal pad on a heat pipe and a second thermal pad on the heat pipe; attaching a package component to the first thermal pad, wherein the package component includes thermal vias; forming a support ring structure, including placing a thermoelectric cooler (TEC) into an opening in a support ring; attaching the support ring structure to the package substrate, including attaching the TEC to the second thermal pad; and attaching a cooling system to the package component and to the support ring structure. In an embodiment, the method includes depositing a sealing material between the TEC and sidewalls of the opening. In an embodiment, a first thermal via is bonded to the first thermal pad. In an embodiment, the thermal vias are arranged in an array pattern. In an embodiment, the thermal vias are arranged in clusters, wherein each cluster includes a set of adjacent thermal vias. In an embodiment, the support ring structure extends over the package component.

In an embodiment, a structure includes a first die including first thermal vias extending through the first die; a first substrate including first thermal pads and second thermal pads on first heat pipes, wherein the first die is bonded to the first thermal pads; a support structure on the first substrate and encircling the first die, wherein the support structure includes first thermoelectric coolers (TEC) over the second thermal pads; and a heat spreader over the first die and the support structure. In an embodiment, the first TECs laterally surround the first die. In an embodiment, the structure includes a second substrate bonded to the first substrate, wherein the second substrate includes second thermal pads on second heat pipes. In an embodiment, the structure includes second TECs attached to the second substrate over the second heat pipes. In an embodiment, the structure includes a cooling system attached to the heat spreader and to the second TECs. In an embodiment, the first substrate includes second thermal vias extending through the first substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a package substrate comprising a plurality of heat pipes;
a package component attached to the package substrate, wherein the package substrate overlaps the plurality of heat pipes;
a support ring attached to the package substrate, wherein the support ring surrounds the package component, wherein the support ring overlaps the plurality of heat pipes;
a plurality of thermoelectric coolers (TECs) within the support ring; and
a heat spreader attached to the package component.

2. The package of claim 1, wherein the package substrate overlaps respective first ends of the plurality of heat pipes, wherein the support ring overlaps respective second ends of the plurality of heat pipes.

3. The package of claim 1, wherein the plurality of TECs are respectively disposed within a plurality of openings in the support ring.

4. The package of claim 1, wherein the plurality of TECs respectively overlap the plurality of heat pipes.

5. The package of claim 1, wherein the heat spreader covers the support ring.

6. The package of claim 1, wherein the heat spreader and the support ring are parts of a lid.

7. The package of claim 1, further comprising a liquid cooling system attached to the heat spreader.

8. The package of claim 1, wherein the package component comprises a plurality of thermal vias, wherein the thermal vias overlap the plurality of heat pipes.

9. A structure comprising:
a first substrate comprising:
a first heat pipe;
a first thermal pad over the first heat pipe; and
a second thermal pad over the first heat pipe;
a second substrate comprising a thermal via extending through the second substrate, wherein the second substrate is bonded to the first substrate, wherein the thermal via is over the first thermal pad;
a first die bonded to the second substrate over the thermal via;
a support structure attached to the first substrate adjacent the second substrate, wherein the support structure comprises a first thermoelectric cooling (TEC) component, wherein the first TEC component is over the second thermal pad; and
a heat spreader attached to the support structure, wherein the heat spreader is over the first TEC component and the first die.

10. The structure of claim 9, further comprising a support substrate attached to the first die, wherein the heat spreader is attached to the support substrate.

11. The structure of claim 9, wherein the first substrate comprises a first routing structure, wherein the first heat pipe is within the first routing structure.

12. The structure of claim 9, wherein the first thermal pad extends from a top surface of the first substrate to a top surface of the first heat pipe.

13. The structure of claim 9, further comprising:
a third substrate comprising a second heat pipe, wherein the first substrate is attached to the third substrate; and
a second TEC component attached to the third substrate.

14. The structure of claim 13, further comprising a cooling system attached to the heat spreader and to the second TEC component.

15. A method comprising:
attaching a package component to a first package substrate, wherein the first package substrate comprises a plurality of heat pipes;
attaching a support ring to the first package substrate, wherein the support ring surrounds the package component, wherein the support ring comprises a plurality of openings;
placing a plurality of thermoelectric coolers (TECs) into the plurality of openings; and
attaching a heat spreader to the package component and to the support ring.

16. The method of claim 15, wherein the support ring is attached to the first package substrate after placing the plurality of TECs into the plurality of openings.

17. The method of claim 15, wherein the support ring and the plurality of TECs have a same thickness.

18. The method of claim 15, further comprising, after placing the plurality of TECs into the plurality of openings, depositing a fill material into the plurality of openings.

19. The method of claim 15, wherein the first package substrate comprises a thermal pad, wherein the support ring is attached to the thermal pad, wherein a width of the thermal pad is greater than a width of a TEC of the plurality of TECs.

20. The method of claim 15, wherein top surfaces of the plurality of TECs are farther from the first package substrate than a top surface of the package component.
